(19) United States
(12) Patent Application Publication
(10) Pub. No.: US 2023/0275076 A1
(43) Pub. Date: Aug. 31, 2023

(54) DISPLAY BACKPLANE ASSEMBLY, LED DISPLAY MODULE, AND RELATED METHODS FOR MANUFACTURING THE SAME

(71) Applicant: CHONGQING KONKA PHOTOELECTRIC TECHNOLOGY RESEARCH INSTITUTE CO., LTD., Chongqing (CN)

(72) Inventor: Feng ZHAI, Chongqing (CN)

(21) Appl. No.: 18/312,013

(22) Filed: May 4, 2023

Related U.S. Application Data
(63) Continuation of application No. PCT/CN2021/097291, filed on May 31, 2021.

(51) Int. Cl. H01L 25/16; H01L 33/00; H01L 23/00; H01L 21/66

(52) U.S. Cl. CPC H01L 25/167; H01L 33/0093; H01L 24/05; H01L 24/95; H01L 22/22; H01L 24/06; H01L 24/08; H01L 24/03; H01L 24/80; H01L 2224/95001; H01L 2224/02175; H01L 2224/03013; H01L 2224/03318; H01L 2224/05073; H01L 2224/05022; H01L 2224/05578; H01L 2224/05609; H01L 2224/05686; H01L 2224/05562; H01L 2224/05571; H01L 2224/06505; H01L 2224/08502; H01L 2224/08123; H01L 2224/08145; H01L 2224/80203; H01L 2224/80805; H01L 2924/12041

(57) ABSTRACT

A display backplane assembly, a light-emitting diode (LED) display module and a device, and related methods for manufacturing the same are provided in the disclosure. The display backplane assembly includes a display backplane and a planarization layer. The display backplane has a first surface, and electrode connecting pads are disposed on the first surface. The planarization layer is stacked on the first surface and defines multiple accommodating holes extending in a thickness direction of the planarization layer. The multiple accommodating holes correspond to the electrode connection pads. Each of the multiple accommodating holes includes a first hole and a second hole. A bonding material is filled in the first hole and in contact with the electrode connection pad. An adhesive is filled in the second hole.

### CROSS-REFERENCE TO RELATED APPLICATION(S)

This application is a continuation of International Application No. PCT/CN2021/097291, filed May 31, 2021, the entire disclosure of which is hereby incorporated by reference.

### TECHNICAL FIELD

The disclosure relates to the field of display, particularly to a display backplane assembly, a light-emitting diode (LED) display module and a device, and related methods for manufacturing the same.

### BACKGROUND

Currently, as a new-generation display technology, micro light-emitting diode (micro LED) display panels have advantages such as a high brightness, a high light-emitting efficiency, and a low power consumption, which makes micro LEDs widely used.

A micro-LED display panel generally has multiple pixel regions, and in each of the pixel regions there are a red LED chip, a blue LED chip, and a green LED chip. During manufacture of the display panel, it needs to transfer the three types of chips from their respective growth substrates to a display backplane. A transferring method used currently includes the following. Prepare a temporary substrate and adhere red LED chips to the temporary substrate. Laser lift-off the growth substrate of the red LED chips, so that the red LED chips are transferred to the temporary substrate. And then, transfer the red LED chips from the temporary substrate to the display backplane by using a transfer substrate. Blue LED chips and green LED chips are respectively transferred in the same process. The process of transferring LED chips to the display backplane is also known as a process of mass bonding.

However, for a current bonding method, an electrical connection stability is tested after bonding. At this point, a connection strength between LED chips and the display backplane is relatively high. If a defective pixel is detected during testing, a relatively large external force is required to remove a defective LED chip, and thus the operation is relatively difficult and bonding materials are easily removed as well, and it is difficult to subsequently trim another LED chip to a position of the defective pixel.

### SUMMARY

In a first aspect of the disclosure, a display backplane assembly is provided. The display backplane assembly includes a display backplane and a planarization layer. The display backplane has a first surface, and electrode connecting pads are disposed on the first surface. The planarization layer is stacked on the first surface and defines multiple accommodating holes extending in a thickness direction of the planarization layer. The multiple accommodating holes correspond to the electrode connection pads. Each of the multiple accommodating holes includes a first hole and a second hole. The first hole extends through the planarization layer in the thickness direction, so that each of the electrode connection pads is at least partially exposed relative to the planarization layer. The second hole extends through at least a side face of the planarization layer away from the display backplane. A bonding material is filled in the first hole and in contact with the electrode connection pad. An adhesive is filled in the second hole. The bonding material is used to electrically connect an electrode of an LED chip with the electrode connecting pad, and the adhesive is used to adhere the LED chip to the planarization layer.

In a second aspect of the disclosure, an LED display module is provided. The LED display module includes an LED chip and the display backplane assembly in the first aspect of the disclosure. The LED chip is disposed on a side face of the planarization layer away from the display backplane. The LED chip has the electrode. The electrode corresponds to at least part of the first hole and at least part of the second hole. The electrode is electrically connected with the electrode connecting pad through the bonding material. The electrode is connected with the planarization layer through the adhesive.

In a third aspect of the disclosure, a method for manufacturing a display backplane assembly is provided. The method includes the following. Prepare a planarization layer on a first surface of a display backplane, where electrode connecting pads are disposed on the first surface. Define multiple accommodating holes on the planarization layer in a thickness direction. The multiple accommodating holes correspond to the electrode connection pads. Each of the electrode connecting pads is at least partially exposed relative to the planarization layer. Each of the multiple accommodating holes includes a first hole and a second hole. The first hole extends through the planarization layer in the thickness direction so that the electrode connecting pad is at least partially exposed relative to the planarization layer. The second hole extends through a side face of the planarization layer away from the display backplane in the thickness direction. Fill a bonding material in the first hole, where the bonding material contacts the electrode connecting pad. Fill an adhesive in the second hole.

In a fourth aspect of the disclosure, a method for trimming the LED display module in the second aspect of the disclosure. The method includes the following. Test an electrical connection stability of the LED chip. Remove the LED chip from the display backplane assembly on a determination that the electrical connection stability of the LED chip is abnormal. Add another LED chip to the display backplane assembly. The another LED chip has an electrode. The electrode of the another LED chip corresponds to the at least part of the first hole and the at least part of the second hole. The electrode is electrically connected with the electrode connecting pad through the bonding material. The electrode is connected with the planarization layer through the adhesive.

### BRIEF DESCRIPTION OF THE DRAWINGS

In order to describe technical solutions in implementations of the disclosure or the related art more clearly, accompanying drawings required for describing implementations or the related art are briefly introduced below. Apparently, the accompanying drawings in the following illustration are merely some implementations of the disclosure. Those of ordinary skill in the art may also obtain other drawings based on these accompanying drawings without creative efforts.

FIG. 1 is a schematic structural view of a growth substrate provided in implementations of the disclosure.

FIG. 2 is a schematic structural view of a growth substrate provided in implementations of the disclosure, from another view.

FIG. 3 is a schematic structural view of a growth substrate and a temporary substrate adhered to the growth substrate provided in implementations of the disclosure.

FIG. 4 is a schematic structural view illustrating a process of transferring light- emitting diode (LED) chips on a growth substrate to a temporary substrate provided in implementations of the disclosure.

FIG. 5 is a schematic structural view of a temporary substrate with transferred LED chips provided in implementations of the disclosure.

FIG. 6 is a schematic structural view of a temporary substrate with transferred LED chips provided in implementations of the disclosure, from another view.

FIG. 7 is a schematic structural view illustrating transferring LED chips to a display backplane through a transfer substrate provided in implementations of the disclosure.

FIG. 8 is a schematic structural view of a display backplane with transferred LED chips provided in implementations of the disclosure.

FIG. 9 is a schematic structural view of a display backplane assembly provided in implementations of the disclosure.

FIG. 10 is a schematic structural view of a display backplane assembly provided in another implementation of the disclosure.

FIG. 11 is a schematic structural view of a display backplane assembly provided in yet another implementation of the disclosure.

FIG. 12 is a schematic structural view of a display backplane assembly provided in still another implementation of the disclosure.

FIG. 13 is a schematic structural view of a display backplane assembly provided in another implementation of the disclosure.

FIG. 14 is a schematic structural view of an LED display module provided in implementations of the disclosure.

FIG. 15 is a flowchart illustrating a process of manufacturing a display backplane assembly provided in implementations of the disclosure.

FIG. 16 is a schematic diagram illustrating a method for manufacturing a display backplane assembly provided in implementations of the disclosure.

FIG. 17 is a schematic view illustrating a process for manufacturing an LED display module provided in implementations of the disclosure.

FIG. 18 is a flowchart illustrating a method for manufacturing an LED display module provided in implementations of the disclosure.

FIG. 19 is a schematic view illustrating a process of trimming an LED display module provided in implementations of the disclosure.

FIG. 20 is a flowchart illustrating a method for trimming an LED display module provided in implementations of the disclosure.

### REFERENCE SIGNS

10—growth substrate,

20—LED chip,

30—temporary substrate,

40—transfer substrate;

100—display backplane,

110—electrode connecting pad,

200—planarization layer,

210—accommodating hole,

211—first hole,

212—second hole,

300—bonding material,

400—adhesive,

X—thickness direction,

Y—horizontal direction.

### DETAILED DESCRIPTION

To facilitate understanding of the disclosure, the disclosure is described more comprehensively with reference to accompanying drawings. The drawings illustrate preferred implementations of the disclosure. However, the disclosure can be implemented in many different implementations and is not limited to implementations described herein. On the contrary, these implementations are provided to make the disclosure be understood more thorough and comprehensive.

Unless otherwise defined, all technical and scientific terms used herein have the same meaning as commonly understood by ordinary skill in the art to which the disclosure belongs. Terms used in the specification of the disclosure are for the purpose of describing particular implementations only and are not intended to limit the disclosure.

In view of shortcomings in the related art, the disclosure aims to provide a display backplane assembly, a light-emitting diode (LED) display module, and related methods for manufacturing the same, to solve problems of difficult removal of defective LED chips and a subsequent difficulty in trimming another LED chip.

The display backplane assembly includes a display backplane and a planarization layer. The display backplane has a first surface, and electrode connecting pads are disposed on the first surface. The planarization layer is stacked on the first surface and defines multiple accommodating holes extending in a thickness direction of the planarization layer. The multiple accommodating holes correspond to the electrode connection pads. Each of the multiple accommodating holes includes a first hole and a second hole. The first hole extends through the planarization layer in the thickness direction, so that each of the electrode connection pads is at least partially exposed relative to the planarization layer. The second hole extends through at least a side face of the planarization layer away from the display backplane. A bonding material is filled in the first hole and in contact with the electrode connection pad. An adhesive is filled in the second hole. The bonding material is used to electrically connect an electrode of an LED chip with the electrode connecting pad, and the adhesive is used to adhere the LED chip to the planarization layer.

The bonding material contacts the electrode of the LED chip but does not fix the LED chip. In some implementations, the bonding material electrically connects the electrode of the LED chip with the electrode connecting pad, but the bonding material does not establish a fixed connection between the electrode of the LED chip and the electrode connecting pad. The adhesive adheres the electrode of the LED chip to the planarization layer, thereby pre-connecting the LED chip on the display backplane. In some implementations, the electrode of the LED chip is attached to the planarization layer via the adhesive, but the adhesive does not establish a fixed connection between the electrode of the LED chip and the planarization layer. At this point, the LED chip is electrically connected with the display backplane, and thus an electrical connection stability of the LED chip can be tested. If a defective pixel is detected during testing, a defective LED chip can be easily removed by a relatively small external force since the LED chip is pre-connected through the adhesive, and thus the operation is relatively simple. Additionally, since the bonding material only contacts the electrode of the LED chip without fixing the LED chip, it can avoid an influence of the defective LED chip on the bonding material, and thus a subsequent trimming of another LED chip can be relatively easy.

Optionally, the first holes and the second holes are alternately arranged at intervals in a direction perpendicular to the thickness direction of the planarization layer. Therefore, relatively uniform contacts between adhesives and the electrode of the LED chip can be realized, and thereby increasing a stability of the LED chip that is pre-connected. Additionally, relatively uniform contacts between bonding materials and the electrode of the LED chip can be realized, and thus the electrical connection stability and a connection strength after subsequent bonding can be improved.

Optionally, each two adjacent accommodating holes have a space therebetween in the direction perpendicular to the thickness direction of the planarization layer, and the space has a size in a radial direction of the accommodating hole that is larger than a diameter of the accommodating hole. In this way, difficulty of processing the accommodating holes can be reduced, and thus costs are reduced.

Optionally, the size a of the space and the diameter b of the accommodating hole satisfy 2*b≤a≤2.5*b. In this way, a sufficient contact area between the bonding material and the LED chip can be ensured, while costs can be reduced.

Optionally, a diameter of the accommodating hole at one end close to the display backplane is larger than a diameter of the accommodating hole at the other end away from the display backplane. In this way, the bonding material and the adhesive can be printed well through jet printing, and thus an operational convenience can be increased.

Alternatively, the diameter of the accommodating hole at the one end close to the display backplane is smaller than the diameter of the accommodating hole at the other end away from the display backplane. In this way, a contact area between the bonding material and the electrode of the LED chip can be relatively large, and thus an electrical connection strength can be increased. A contact area between the adhesive and the electrode of the LED chip can also be relatively large, and thus the stability of the pre-connected LED chip can be enhanced.

Optionally, a diameter of the first hole at one end close to the display backplane is larger than a diameter of the first hole at the other end away from the display backplane, and a diameter of the second hole at one end close to the display backplane is smaller than a diameter of the second hole at the other end away from the display backplane. In this way, the contact area between the adhesive and the electrode of the LED chip can be increased, thereby enhancing the stability of the pre-connected LED chip, and facilitating printing of the bonding material in the first hole through jet printing.

Alternatively, the diameter of the first hole at the one end close to the display backplane is smaller than the diameter of the first hole at the other end away from the display backplane, and the diameter of the second hole at the one end close to the display backplane is larger than the diameter of the second hole at the other end away from the display backplane. In this way, the contact area between the bonding material and the electrode of the LED chip can be increased, and thus the electrical connection stability of the LED chip can be enhanced. In addition, a preparation of an adhesive material in the second hole can be facilitated.

Optionally, the bonding material is flush with a surface of the planarization layer away from the display backplane. Alternatively, the bonding material exceeds the surface of the planarization layer away from the display backplane. In this way, a contact reliability between the bonding material and the electrode of the LED chip can be improved.

Optionally, the second hole further extends through a side face of the planarization layer facing the display backplane. In this way, processing difficulty can be reduced, and costs can be saved.

Optionally, the planarization layer is made of at least one of polymethyl methacrylate, polystyrene, a polymer derivative with a phenolic group, an acrylic polymer, an imide-based polymer, an arylether-based polymer, an amide-based polymer, a fluorine-based polymer, a p-xylene-based polymer, or a vinyl alcohol-based polymer.

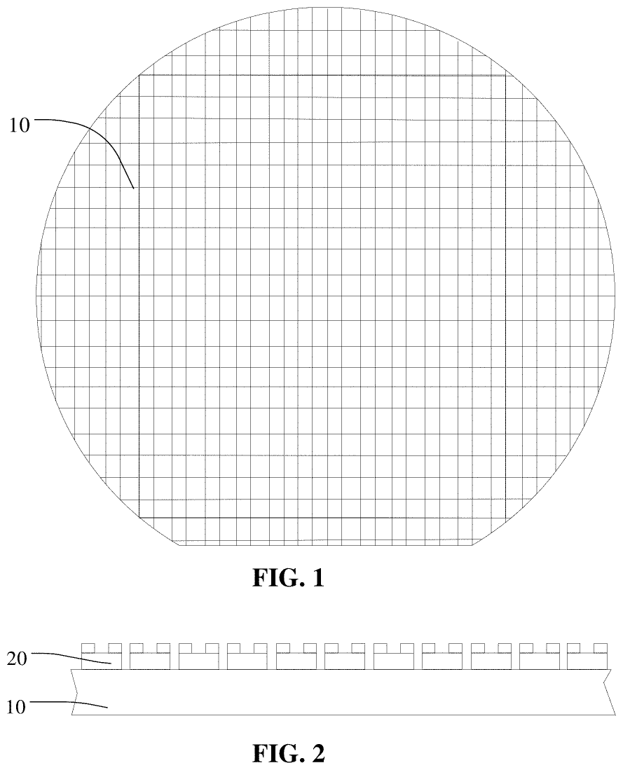

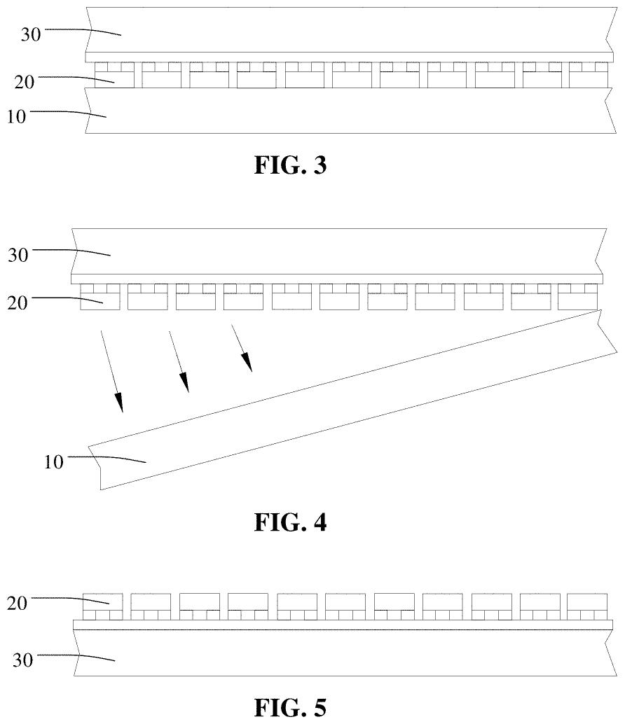

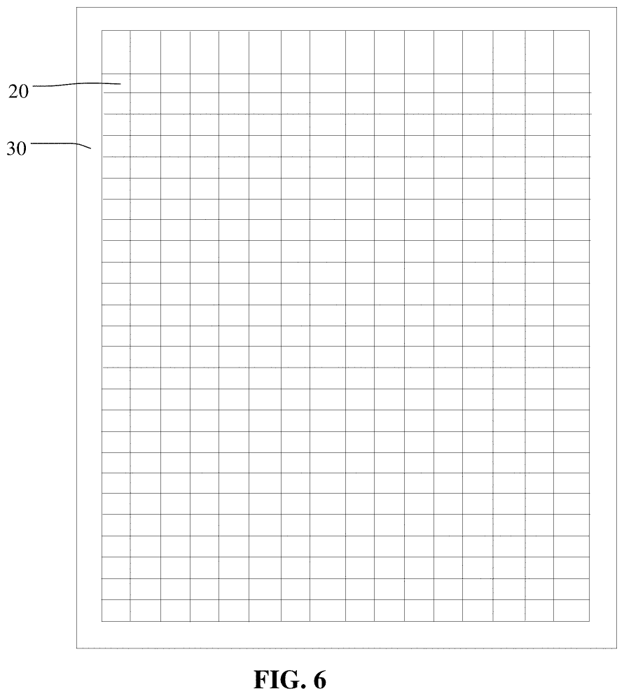

Referring to FIGS. 1 to 6. FIG. 1 is a schematic structural view of a growth substrate provided in implementations of the disclosure. FIG. 2 is a schematic structural view of a growth substrate provided in implementations of the disclosure, from another view. FIG. 3 is a schematic structural view of a growth substrate and a temporary substrate adhered to the growth substrate provided in implementations of the disclosure. FIG. 4 is a schematic structural view illustrating a process of transferring light-emitting diode (LED) chips on a growth substrate to a temporary substrate provided in implementations of the disclosure. FIG. 5 is a schematic structural view of a temporary substrate with transferred LED chips provided in implementations of the disclosure. FIG. 6 is a schematic structural view of a temporary substrate with transferred LED chips provided in implementations of the disclosure, from another view.

In general, red, blue, and green LED chips are transferred separately when transferring LED chips 20 to a display backplane 100. As an example, one type of LED chips 20 is described as follows for illustration, and the same applies to the other two types of LED chips, which are not further described in the disclosure.

Transferring the LED chips 20 to the display backplane 100 includes the following.

At S10, provide a growth substrate 10 (for example, a wafer) with LED chips 20 grown on the growth substrate 10. Adhere the LED chips 20 to a temporary substrate 30 via an adhesive layer on the temporary substrate 30. And then, lift-off the growth substrate 10 from the LED chips 20. In this way, the LED chips 20 can be transferred to the temporary substrate 30.

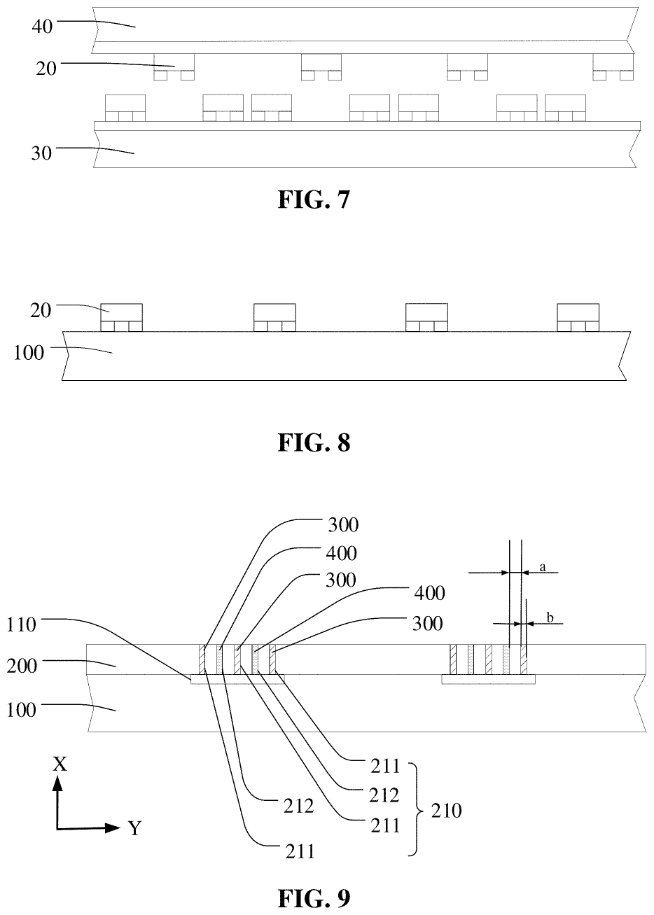

At S11, adhere selectively the LED chips 20 to a transfer substrate 40 via the adhesive layer on the transfer substrate 40. Referring to FIG. 7, FIG. 7 illustrates that the LED chips 20 is selectively adhered to the transfer substrate 40 from the temporary substrate 30.

At S12, transfer the LED chips 20 on the transfer substrate 40 to the display backplane 100. Referring to FIG. 8, FIG. 8 is a schematic view illustrating that the LED chips 20 have been transferred to the display backplane 100. A process of transferring LED chips 20 to the display backplane 100 through the transfer substrate 40 is also known as a process of mass bonding. Therefore, gold-indium eutectic bonding of the LED chip 20 is completed after the transfer.

After the transfer is completed, that is, after the gold-indium eutectic bonding is completed, an electrical connection stability of the LED chip 20 is tested. If a defective pixel is detected during testing, a defective LED chip 20 is removed, and then another LED chip 20 is added to a position of the defective pixel. However, for a current bonding method, the electrical connection stability is tested after the gold-indium eutectic bonding. At this point, a connection strength between the LED chips 20 and the display backplane 100 is relatively high. If the defective pixel is detected during testing, a relatively large external force is required to remove the defective LED chip 20, and thus the operation is relatively difficult and bonding materials are easily removed as well, and it is difficult to subsequently trim another LED chip 20 to the position of the defective pixel.

Based on this, the disclosure aims to provide a display backplane assembly, an LED display module and a device, and related methods for manufacturing the same that can solve the above technical problems, and details thereof are described in the following implementations.

Referring to FIG. 9, FIG. 9 is a schematic structural view of a display backplane assembly provided in implementations of the disclosure. The display backplane assembly provided in implementations of the disclosure includes a display backplane 100 and a planarization layer 200. The planarization layer 200 is made of a non-conductive material.

The display backplane 100 has a first surface and a second surface disposed opposite the first surface. In FIG. 9, an upper surface of the display backplane 100 serves as the first surface, and a lower surface of the display backplane 100 serves as the second surface. Electrode connecting pads 110 are disposed on the first surface. The planarization layer 200 is stacked on the first surface and defines multiple accommodating holes 210 extending in a thickness direction X of the planarization layer. The multiple accommodating holes 210 correspond to the electrode connecting pads 110. Each of the multiple accommodating holes 210 includes a first hole 211 and a second hole 212. The first hole 211 extends through the planarization layer 200 in the thickness direction X so that each of the electrode connecting pads 110 is at least partially exposed relative to the planarization layer 200, and the second hole 212 extends through at least a side face of the planarization layer 200 away from the display backplane 100 in the thickness direction X. A bonding material 300 is filled in the first hole 211, and in contact with the electrode connecting pad 110. An adhesive 400 is filled in the second hole 212.

The bonding material 300 is used to electrically connect an electrode of an LED chip 20 with the electrode connecting pad 110, and the adhesive 400 is used to attach the LED chip 20 to the planarization layer 200. Specifically, the LED chip 20 is disposed on a side face of the planarization layer 200 away from the display backplane 100. The LED chip 20 has the electrode. The electrode corresponds to at least part of the first hole 211 and at least part of the second hole 212. The electrode is electrically connected with the electrode connecting pad 110 through the bonding material 300, and the electrode is connected with the planarization layer 200 through the adhesive 400. In some implementations, the bonding material 300 electrically connects the electrode of the LED chip 20 with the electrode connecting pad 110, but the bonding material 300 does not establish a fixed connection between the electrode of the LED chip 20 and the electrode connecting pad 110. In some implementations, the electrode of the LED chip 20 is attached to the planarization layer 200 via the adhesive 400, but the adhesive 400 does not establish a fixed connection between the electrode of the LED chip 20 and the planarization layer 200.

The display backplane 100 mentioned above can be a thin film transistor (TFT) circuit board, and the bonding material 300 can be metal indium. The bonding material 300 has a relatively high reliability after bonding. The adhesive 400 can be made of a non-conductive film (NCF) adhesive material, which has a relatively low cost and a suitable adhesion strength. The adhesive 400 is made of a non-conductive material.

The material of the planarization layer 200 includes at least one of organic materials, such as polymethyl methacrylate, polystyrene, a polymer derivative with a phenolic group, an acrylic polymer, an imide-based polymer, an arylether-based polymer, an amide-based polymer, a fluorine-based polymer, a p-xylene-based polymer, or a vinyl alcohol-based polymer. That is, the planarization layer 200 can be made of any of the above materials or a mixture of two or more of the above materials. The selected materials are relatively easy to obtain, low in cost, and convenient to process.

In the implementations, the planarization layer 200 is stacked on the display backplane 100. The planarization layer 200 can eliminate a step difference of a circuit backplane caused by a processing accuracy difference and is conducive to the connection between the display backplane 100 and the LED chip 20. Specifically, the accommodating holes 210 are defined on the planarization layer 200 corresponding to the electrode connecting pads 110. The bonding material 300 is filled in the first hole 211 of the accommodating holes 210, and the adhesive 400 is filled in the second hole 212 of the accommodating holes 210. Then, the electrode of the LED chips 20 is aligned with the accommodating hole 210. At this point, the bonding material 300 contacts the electrode of the LED chip 20 on an upper side face and contacts the electrode connecting pads 110 on a lower side face, thereby electrically connecting the LED chip 20 with the electrode connecting pads 110. The adhesive 400 adheres the electrodes of the LED chip 20 to the planarization layer 200, thereby pre-connecting the LED chip 20 with the display backplane 100.

Since the LED chip 20 is electrically connected with the display backplane 100 during pre-connecting, the electrical connection stability of the LED chip 20 can be tested after pre-connecting. If a defective pixel is detected during testing, a defective LED chip 20 can be removed, and another LED chip 20 can be installed. When removing the defective LED chip 20, the defective LED chip 20 can be easily removed by a relatively small external force since the LED chip 20 is pre-connected but not fixed through the adhesive 400, and thus the operation is relatively simple. Additionally, since the bonding material 300 only contacts the electrode of the LED chip 20 without fixing the LED chip, it can avoid the influence of the defective LED chip 20 on the bonding material 300, and thus the subsequent trimming of another LED chip 20 can be relatively easy.

After trimming, a soft pressure plate can be used to cover the LED chip 20, and then perform heating and pressing to complete mass bonding of the LED chip 20, that is, to complete the gold-indium eutectic bonding. At this point, the LED chip 20 is also fixedly connected with the bonding material 300, and thus the electrical connection stability can be ensured. The soft pressure plate consists of a hard quartz substrate and a transfer substrate or a polyurethane adhesive layer on the hard quartz substrate, and can prevent, through gentle pressure, the LED chip 20 from being damaged when heating and pressing the LED chip 20.

As those skilled in the art can understand, the LED chip 20 generally has two electrodes, i.e., one positive electrode and one negative electrode. Therefore, each LED chip 20 needs to correspond to two electrode connecting pads 110, i.e., one positive electrode connecting pad 110 and one negative electrode connecting pad 110. As shown in the drawings, the two electrodes of the LED chip 20 are in one-to-one correspondence with the two electrode connecting pads 110.

In some implementations, the first holes 211 and the second holes 212 are alternately arranged at intervals in a direction perpendicular to the thickness direction X of the planarization layer 200. In the drawing, an X direction is the thickness direction X, and a Y direction is a horizontal direction Y (i.e., the direction perpendicular to the thickness direction X of the planarization layer 200). Since the first holes 211 are filled with the bonding materials 300, and the second holes 212 are filled with the adhesives 400, the first holes 211 and the second holes 212 are alternately arranged at intervals, that is, the bonding materials 300 and the adhesives 400 are alternately arranged at intervals. In this way, relatively uniform contacts between the adhesives 400 and the electrode of the LED chip 20 can be realized, and thereby increasing the stability of the LED chip 20 that is pre-connected. Additionally, relatively uniform contacts between the bonding materials 300 and the electrode of the LED chip 20 can be realized, and thus the electrical connection stability and the connection strength after subsequent bonding can be improved.

In some implementations, each two adjacent accommodating holes 210 have a space therebetween in the direction perpendicular to the thickness direction X of the planarization layer 200, and the space has a size in a radial direction of the accommodating hole 210 that is larger than a diameter of the accommodating hole 210. In this way, the two adjacent accommodating holes 210 can be avoided from being communicated due to a too small size of the space under an influence of the processing accuracy. Processing difficulty of the accommodating holes 210 can be reduced by setting the size of the space larger than the diameter of the accommodating holes 210, thereby reducing costs.

Exemplarily, the size a of the space and the diameter b of the accommodating hole 210 satisfy 2*b≤a≤2.5*b. If the space is too large, the number of the accommodating holes 210 can be set on the planarization layer 200 corresponding to the electrode connecting pads 110 is relatively small, and thus an amount of the corresponding bonding material 300 and the corresponding adhesive 400 filled is relatively small. This results in a decreased contact area between the bonding material 300 and the electrode of the LED chip 20, which consequently increases resistance, and affects the connection strength of the bonding and an adhesion stability. If the space is too small, high processing accuracy is required, leading to an increase in costs. By setting 2*b≤a≤2.5*b, a sufficient contact area between the bonding material 300 and the LED chip 20 can be ensured, while the costs can also be ensured.

In some implementations, as illustrated in FIG. 9, a diameter of the accommodating hole 210 at one end close to the display backplane 100 is equal to a diameter of the accommodating hole 210 at the other end away from the display backplane 100. That is, the accommodating hole 210 has a diameter that is consistent from top to bottom, which can facilitate processing.

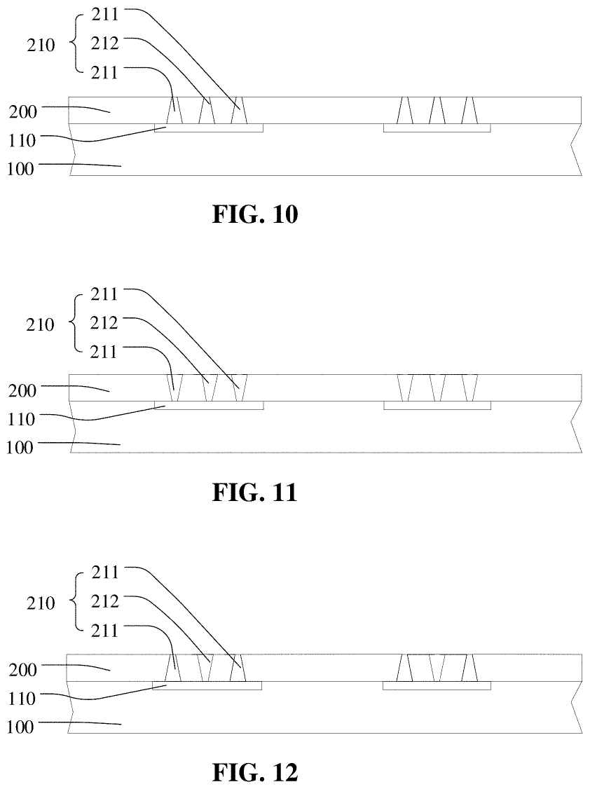

Referring to FIG. 10, FIG. 10 is a schematic structural view of a display backplane assembly provided in another implementation of the disclosure. In some implementations, the diameter of the accommodating hole 210 at the one end close to the display backplane 100 is larger than the diameter of the accommodating hole 210 at the other end away from the display backplane 100. In the drawing, the diameter of each of the accommodating holes 210 gradually increases from top to bottom, presenting a smaller-top and larger-bottom shape. Therefore, when the bonding material 300 is filled in the first hole 211, nano-silver can be used as the bonding material 300 and be printed on the planarization layer 200 through electrohydrodynamic jet printing. After a nano-silver layer printed is solidified, another nano-silver layer can be sprayed on the solidified nano-silver layer until the nano-silver is filled in the entire first hole 211. The smaller-top and larger-bottom structure is relatively suitable for printing nano-silver. When the NCF adhesive material is printed to fill the second hole 212, the smaller-top and larger-bottom structure of the second hole 212 also facilitates the printing of NCF adhesive material.

Referring to FIG. 11, FIG. 11 is a schematic structural view of a display backplane assembly provided in yet another implementation of the disclosure. In some other implementations, the diameter of the accommodating hole 210 at the one end close to the display backplane 100 is smaller than the diameter of the accommodating hole 210 at the other end away from the display backplane 100. In other words, the diameter of the accommodating hole 210 gradually decreases from top to bottom, presenting a larger-top and smaller-bottom shape. In this case, the contact area between the bonding material 300 and the electrode of the LED chip 20 is relatively large, such that the strength of the electrical connection can be increased. The contact area between the adhesive 400 and the electrode of the LED chip 20 is also relatively large, such that the stability of the pre-connected LED chip 20 can be increased.

Referring to FIG. 12, FIG. 12 is a schematic structural view of a display backplane assembly provided in still another implementation of the disclosure. In some other implementations, the diameter the first hole 211 at the one end close the display backplane 100 is larger than the diameter of the first hole 211 at the other end away from the display backplane 100, and a diameter of the second hole 212 at the one end close to the display backplane 100 is smaller than the diameter of the second hole 212 at the other end away from the display backplane 100. In other words, the diameter of the first hole 211 gradually increases from top to bottom, while the diameter of the second hole 212 gradually decreases from top to bottom. As a result, the contact area between the adhesive 400 and the electrode of the LED chip 20 can be increased, thereby enhancing the stability of the pre-connected LED chip 20; and it is convenient to print nano-silver in the first hole 211.

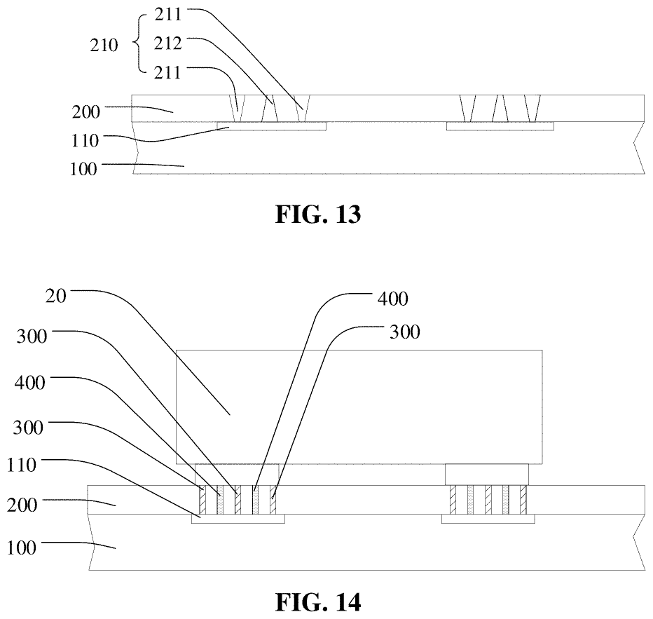

Referring to FIG. 13, FIG. 13 is a schematic structural view of a display backplane assembly provided in another implementation of the disclosure. In some other implementations, the diameter of the first hole 211 at the one end close to the display backplane 100 is smaller than the diameter of the first hole 211 at the other end away from the display backplane 100, and the diameter of the second hole 212 at the one end close the display backplane 100 is larger than the diameter of the second hole 212 at the other end away from the display backplane 100. In other words, the diameter of the first hole 211 gradually decreases from top to bottom, while the diameter of the second hole 212 gradually increases from top to bottom. As a result, the contact area between the bonding material 300 and the electrode of the LED chip 20 can be increased, thereby increasing the electrical connection stability of the LED chip 20, and it is convenient to prepare the adhesive material in the second hole 212.

In order to ensure reliable contact between the bonding material 300 and the electrode of the LED chip 20, the bonding material 300 is set to be flush with a surface of the planarization layer 200 away from the display backplane 100.

In some other implementations, in order to increase the contact reliability between the bonding material 300 and the electrode of the LED chip 20, the bonding material 300 may exceed the surface of the planarization layer 200 away from the display backplane 100. Exemplarily, the bonding material 300 may exceed the planarization layer 200 by 1 micron, such that the electrical connection reliability can be enhanced.

As mentioned above, the second hole 212 is required to extend through the side face of the planarization layer 200 away from the display backplane 100, which is convenient to fill the adhesive 400, and facilitates the contact between the adhesive 400 and the electrode of the LED chip 20, thereby pre-connecting the LED chip 20 with the display backplane 100. In some implementations, the second hole 212 may not extend through a side face of the planarization layer 200 facing the display backplane 100, that is, the second hole 212 may be a blind hole. In other implementations, the second hole 212 also extends through the side face of the planarization layer 200 facing the display backplane 100, that is, the first hole 211 and the second hole 212 both extend through the planarization layer 200. In this way, the processing difficulty can be reduced, and costs can be saved.

Referring to FIG. 14, FIG. 14 is a schematic structural view of an LED display module provided in implementations of the disclosure. Based on the display backplane assembly provided in any of the above implementations, an LED display module is further provided in implementations of the disclosure. The LED display module includes the LED chip 20 and the display backplane assembly of any of the above implementations. The LED chip 20 is disposed on a side face of the planarization layer 200 away from the display backplane 100. The LED chip 20 has the electrode. The electrode corresponds to at least part of the first hole 211 and at least part of the second hole 212. The electrode is electrically connected with the electrode connecting pad 110 through the bonding material 300. The electrode is connected with the planarization layer 200 through the adhesive 400.

In the implementation, the planarization layer 200 is stacked on the display backplane 100 and defines accommodating holes 210 corresponding to the electrode connecting pads 110. The bonding material 300 is filled in the first hole 211 of the accommodating hole 210, and the adhesive 400 is filled in the second hole 212. Then, the electrode of the LED chip 20 is aligned with the accommodating hole 210. At this point, the bonding material 300 contacts the electrodes of the LED chip 20 on an upper side face and contacts the electrode connecting pads 110 on a lower side face, thereby electrically connecting the LED chip 20 with the electrode connecting pads 110. The adhesive 400 adheres the electrodes of the LED chip 20 to the planarization layer 200, thereby pre-connecting the LED chip 20 on the display backplane 100.

Since the LED chip 20 is electrically connected with the display backplane 100 during pre-connecting, the electrical connection stability of the LED chip 20 can be tested after pre-connecting. If a defective pixel is detected during testing, a defective LED chip 20 can be removed, and another LED chip 20 can be installed. When removing the defective LED chip 20, the defective LED chip 20 can be easily removed by a relatively small external force since the LED chip 20 is pre-connected through the adhesive 400, and thus the operation is relatively simple. Additionally, since the bonding material 300 only contacts the electrode of the LED chip 20 without fixing the LED chip, it can avoid the influence of the defective LED chip 20 on the bonding material 300, and thus the subsequent trimming of another LED chip 20 can be relatively easy.

After trimming, a soft pressure plate can be used to cover the LED chip 20, and then perform heating and pressing to complete mass bonding of the LED chip 20, that is, to complete the gold-indium eutectic bonding. At this point, the LED chip 20 is also fixedly connected with the bonding material 300, and thus the electrical connection stability can be ensured. The soft pressure plate consists of a hard quartz substrate and a transfer substrate 40 or a polyurethane adhesive layer on the hard quartz substrate, and can prevent, through gentle pressure, the LED chip 20 from being damaged when heating and pressing the LED chip 20.

An LED display device is further provided in implementations of the disclosure. The LED display device includes the display backplane assembly according to any one of the implementations of the disclosure. The LED display device may be an LED display screen, as well as devices using the LED display screen, such as televisions, computers, and industrial computers.

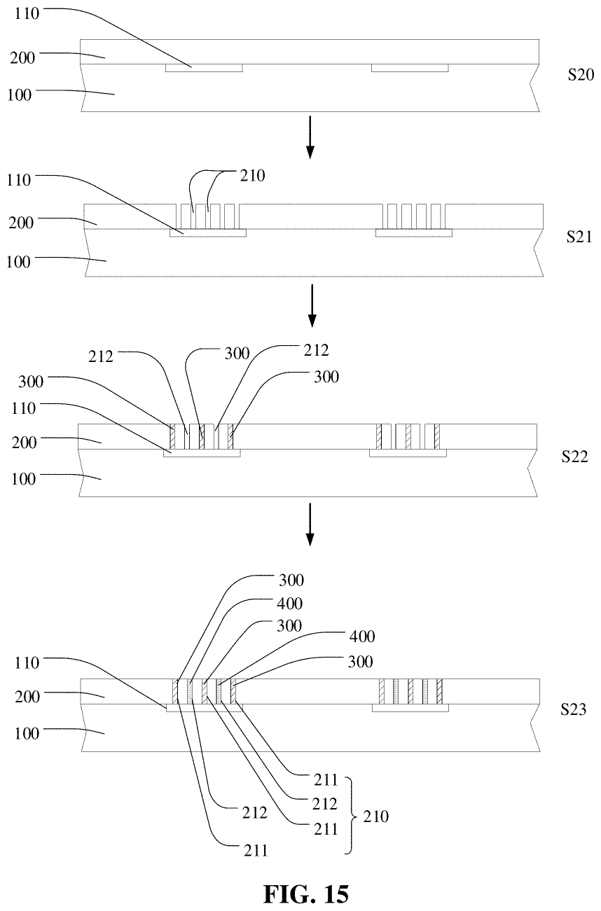

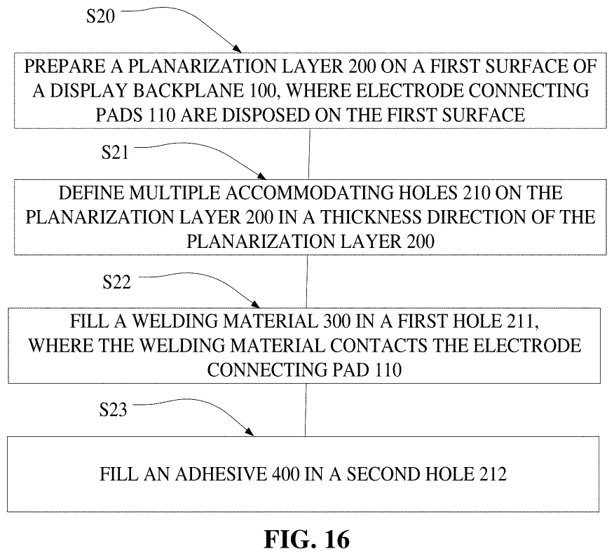

Referring to FIGS. 15 and 16, FIG. 15 is a flowchart illustrating a process of manufacturing a display backplane assembly provided in implementations of the disclosure, and FIG. 16 is a schematic diagram illustrating a method for manufacturing a display backplane assembly provided in implementations of the disclosure. The method for manufacturing the display backplane assembly in the above implementations is elaborated below, and includes the following.

At S20, prepare a planarization layer 200 on a first surface of a display backplane 100, where electrode connecting pads 110 are disposed on the first surface. The planarization layer 200 can be prepared either through jet printing, or by pre-preparing it first and then stacking and fixing it on the display backplane 100.

At S21, define multiple accommodating holes 210 on the planarization layer 200 in a thickness direction X of the planarization layer 200. The multiple accommodating holes 210 correspond to the electrode connecting pads 110. Each of the electrode connecting pads 110 is at least partially exposed relative to the planarization layer 200. Each of the multiple accommodating holes 210 includes a first hole 211 and a second hole 212. The first hole 211 extends through the planarization layer 200 in the thickness direction X so that the electrode connecting pad 110 is at least partially exposed relative to the planarization layer 200. The second hole 212 extends through a side face of the planarization layer 200 away from the display backplane 100 in the thickness direction X. Specifically, microstructures (i.e., the accommodating holes 210) can be prepared through nanoimprint.

At S22, fill a bonding material 300 in the first hole 211, where the bonding material contacts the electrode connecting pad 110. Specifically, a high-precision metal mask can be used to prepare metal indium in the first hole 211. Alternatively, nano-silver can be printed in the first holes 211 through jet printing to serve as the bonding material 300.

At S23, fill an adhesive 400 in the second hole 212. Specifically, a high-precision metal mask can be used to prepare the adhesive 400 in the second hole 212.

For the LED display backplane 100 prepared through the above method, the bonding material 300 is filled in the first hole 211, and the adhesive 400 is filled in the second hole 212. When the LED chip 20 is prepared on the LED display backplane 100, the LED chip 20 and the electrode connecting pad 110 can be electrically connected with but not fixed with each other through the bonding material 300, and the adhesive 400 can adhere the electrode of the LED chip 20 to the planarization layer 200, such that the LED chip 20 can be pre-connected on the display backplane 100. In some implementations, the bonding material 300 electrically connects the electrode of the LED chip 20 with the electrode connecting pad 110, but the bonding material 300 does not establish a fixed connection between the electrode of the LED chip 20 and the electrode connecting pad 110. In some implementations, the electrode of the LED chip 20 is attached to the planarization layer 200 via the adhesive 400, but the adhesive 400 does not establish a fixed connection between the electrode of the LED chip 20 and the planarization layer 200. Since the LED chip 20 is electrically connected with the display backplane 100 during pre-connecting, the electrical connection stability of the LED chip 20 can be tested after pre-connecting. If a defective pixel is detected during testing, a defective LED chip 20 can be removed, and another LED chip 20 can be installed. When removing the defective LED chip 20, the defective LED chip 20 can be easily removed by a relatively small external force since the LED chip 20 is pre-connected through the adhesive 400, and thus the operation is relatively simple. Additionally, since the bonding material 300 only contacts the electrode of the LED chip 20 without fixing the LED chip, it can avoid the influence of the defective LED chip 20 on the bonding material 300, and thus the subsequent trimming of another LED chip 20 can be relatively easy.

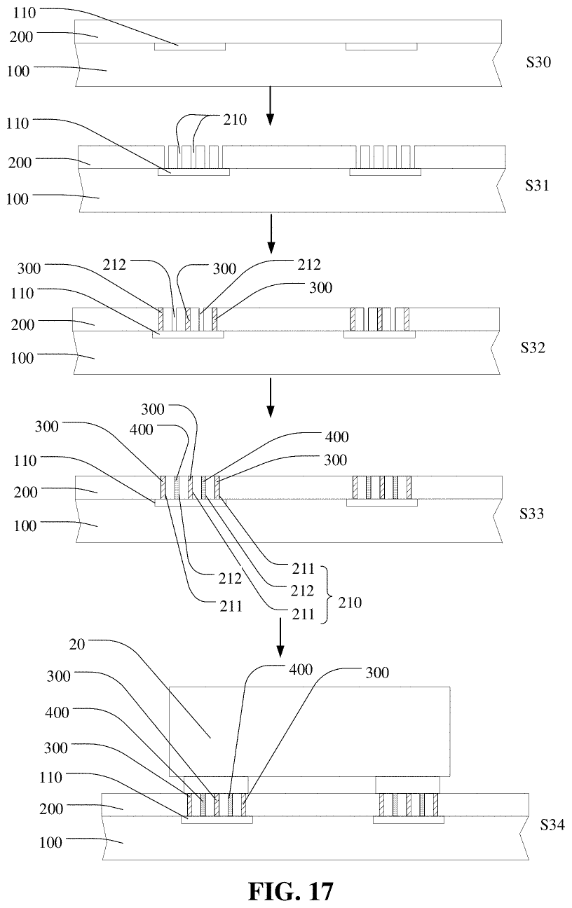

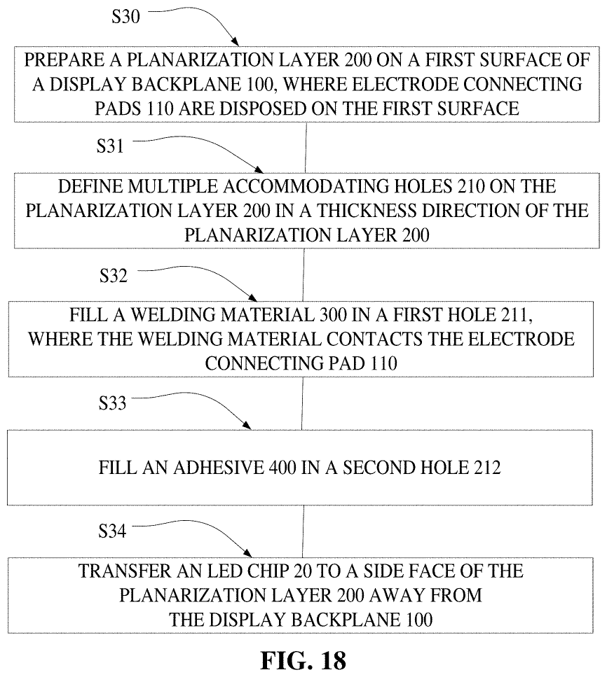

Referring to FIGS. 17 and 18, FIG. 17 is a schematic view illustrating a process for manufacturing an LED display module provided in implementations of the disclosure, and FIG. 18 is a flowchart illustrating a method for manufacturing an LED display module provided in implementations of the disclosure. The method for manufacturing the LED display module mentioned above is elaborated below, and the method includes the following.

At S30, prepare a planarization layer 200 on a first surface of a display backplane 100, where electrode connecting pads 110 are disposed on the first surface. The planarization layer 200 can be prepared either through jet printing, or by pre-preparing it first and then stacking and fixing it on the display backplane 100.

At S31, define multiple accommodating holes 210 on the planarization layer 200 in a thickness direction X of the planarization layer 200. The multiple accommodating holes 210 correspond to the electrode connecting pads 110. Each of the electrode connecting pads 110 is at least partially exposed relative to the planarization layer 200. Each of the multiple accommodating holes 210 includes a first hole 211 and a second hole 212. The first hole 211 extends through the planarization layer 200 in the thickness direction X so that the electrode connecting pad 110 is at least partially exposed relative to the planarization layer 200. The second hole 212 extends through a side face of the planarization layer 200 away from the display backplane 100 in the thickness direction X. Specifically, microstructures (i.e., the accommodating holes 210) can be prepared through nanoimprint.

At S32, fill a bonding material 300 in the first hole 211, where the bonding material contacts the electrode connecting pad 110. Specifically, a high-precision metal mask can be used to prepare metal indium in the first hole 211. Alternatively, nanoparticle silver can be printed in the first holes 211 through jet printing to serve as the bonding material 300.

At S33, fill an adhesive 400 in the second hole 212. Specifically, a high-precision metal mask can be used to prepare the adhesive 400 in the second hole 212.

At S34, transfer an LED chip 20 to a side face of the planarization layer 200 away from the display backplane 100. The LED chip 20 has an electrode. The electrode corresponds to at least part of the first hole 211 and at least part of the second hole 212. The electrode is electrically connected with the electrode connecting pad 110 through the bonding material 300 and the electrode is connected with the planarization layer 200 through the adhesive 400.

For the LED display backplane 100 prepared through the above method, the bonding material 300 is filled in the first hole 211, and the adhesive 400 is filled in the second hole 212. The LED chip 20 and the electrode connecting pad 110 are electrically connected with but not fixed with each other through the bonding material 300, and the adhesive 400 adheres the electrode of the LED chip 20 to the planarization layer 200, such that the LED chip 20 can be pre-connected with the display backplane 100. Since the LED chip 20 is electrically connected with the display backplane 100 during pre-connecting, the electrical connection stability of the LED chip 20 can be tested after pre-connecting. If a defective pixel is detected during testing, a defective LED chip 20 can be removed, and another LED chip 20 can be installed. When removing the defective LED chip 20, the defective LED chip 20 can be easily removed by a relatively small external force since the LED chip 20 is pre-connected through the adhesive 400, and thus the operation is relatively simple. Additionally, since the bonding material 300 only contacts the electrode of the LED chip 20 without fixing the LED chip, it can avoid the influence of the defective LED chip 20 on the bonding material 300, and thus the subsequent trimming of another LED chip 20 can be relatively easy.

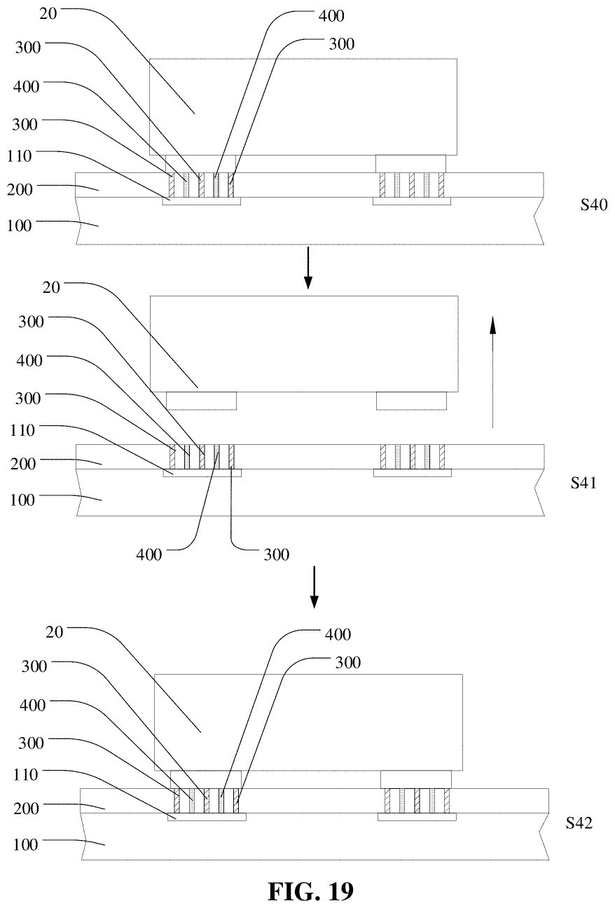

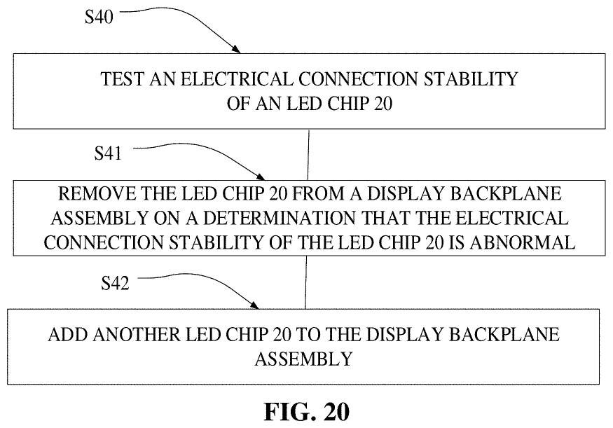

Referring to FIGS. 19 and 20, FIG. 19 is a schematic view illustrating a process of trimming an LED display module provided in implementations of the disclosure, and FIG. 20 is a flowchart illustrating a method for trimming an LED display module provided in implementations of the disclosure. Based on the LED display module in the above implementations, a method for trimming is further provided in implementations of the disclosure.

At S40, test an electrical connection stability of the LED chip 20.

At S41, remove the LED chip 20 from the display backplane assembly on a determination that the electrical connection stability of the LED chip 20 is abnormal.

At S42, add another LED chip 20 to the display backplane assembly. The another LED chip 20 has an electrode. The electrode of the another LED chip 20 corresponds to the at least part of the first hole 211 and the at least part of the second hole 212. The electrode is electrically connected with the electrode connecting pad 110 through the bonding material 300. The electrode is connected with the planarization layer 200 through the adhesive 400.

When removing the defective LED chip 20, the defective LED chip 20 can be easily removed by a relatively small external force since the LED chip 20 is pre-connected through the adhesive 400, and thus the operation is relatively simple. Additionally, since the bonding material 300 only contacts the electrode of the LED chip 20 without fixing the LED chip, it can avoid the influence of the defective LED chip 20 on the bonding material 300, and thus the trimming of another LED chip 20 can be relatively easy.

After trimming, a soft pressure plate can be used to cover the LED chip 20, and then perform heating and pressing to complete mass bonding of the LED chip 20, that is, to complete the gold-indium eutectic bonding. At this point, the LED chip 20 is also fixedly connected with the bonding material 300, and thus the electrical connection stability can be ensured. The soft pressure plate consists of a hard quartz substrate and a transfer substrate or a polyurethane adhesive layer on the hard quartz substrate, and can prevent, through gentle pressure, the LED chip 20 from being damaged when heating and pressing the LED chip 20.

In some implementation, the display backplane 100 may serve as a direct view display or as a driving array component of a backlight unit, which is not limited herein. Exemplarity, the LED display device may be one of a backlight display device, a direct view display device, or a liquid crystal display device.

It should be understood that the disclosure is not limited to implementations mentioned above. For those skilled in the art, improvements or modifications can be made based on the above illustration. All such improvements and modifications should fall within the protection scope of the claims of the disclosure.

What is claimed is:

1. A display backplane assembly, comprising:
a display backplane, the display backplane having a first surface, and electrode connecting pads being disposed on the first surface; and
a planarization layer stacked on the first surface, wherein the planarization layer defines a plurality of accommodating holes extending in a thickness direction of the planarization layer, wherein the plurality of accommodating holes correspond to the electrode connecting pads, each of the plurality of accommodating holes comprises a first hole and a second hole, wherein the first hole extends through the planarization layer in the thickness direction so that each of the electrode connecting pads is at least partially exposed relative to the planarization layer, the second hole extends through at least a side face of the planarization layer away from the display backplane, a bonding material is filled in the first hole and in contact with the electrode connecting pad, and an adhesive is filled in the second hole; wherein the bonding material is used to electrically connect an electrode of a light-emitting diode (LED) chip with the electrode connecting pad, and the adhesive is used to adhere the LED chip to the planarization layer.

2. The display backplane assembly of claim 1, wherein the electrode of the LED chip is in non-fixed connection with the electrode connecting pad.

3. The display backplane assembly of claim 1, wherein the first holes and the second holes are alternately arranged at intervals in a direction perpendicular to the thickness direction of the planarization layer.

4. The display backplane assembly of claim 1, wherein each two adjacent accommodating holes have a space therebetween in the direction perpendicular to the thickness direction of the planarization layer, and the space has a size in a radial direction of the accommodating hole that is larger than a diameter of the accommodating hole.

5. The display backplane assembly of claim 3, wherein the size a of the space and the diameter b of the accommodating hole satisfy 2*b≤a≤2.5*b.

6. The display backplane assembly of claim 1, wherein a diameter of the accommodating hole at one end close to the display backplane is larger than a diameter of the accommodating hole at the other end away from the display backplane; or the diameter of the accommodating hole at the one end close to the display backplane is smaller than the diameter of the accommodating hole at the other end away from the display backplane.

7. The display backplane assembly of claim 1, wherein a diameter of the first hole at one end close to the display backplane is larger than a diameter of the first hole at the other end away from the display backplane, and a diameter of the second hole at one end close to the display backplane is smaller than a diameter of the second hole at the other end away from the display backplane; or the diameter of the first hole at the one end close to the display backplane is smaller than the diameter of the first hole at the other end away from the display backplane, and the diameter of the second hole at the one end close to the display backplane is larger than the diameter of the second hole at the other end away from the display backplane.

8. The display backplane assembly of claim 1, wherein the bonding material is flush with a surface of the planarization layer away from the display backplane; or the bonding material exceeds the surface of the planarization layer away from the display backplane.

9. The display backplane assembly of claim 1, wherein the second hole further extends through a side face of the planarization layer facing the display backplane.

10. The display backplane assembly of claim 1, wherein the planarization layer is made of at least one of polymethyl methacrylate, polystyrene, a polymer derivative with a phenolic group, an acrylic polymer, an imide-based polymer, an arylether-based polymer, an amide-based polymer, a fluorine-based polymer, a p-xylene-based polymer, or a vinyl alcohol-based polymer.

11. The display backplane assembly of claim 1, wherein a diameter of the accommodating hole at one end close to the display backplane is equal to a diameter of the accommodating hole at the other end away from the display backplane.

12. A light-emitting diode (LED) display module, comprising an LED chip and a display backplane assembly, wherein the display backplane assembly comprises:
a display backplane, the display backplane having a first surface, and electrode connecting pads being disposed on the first surface; and
a planarization layer stacked on the first surface, wherein the planarization layer defines a plurality of accommodating holes extending in a thickness direction of the planarization layer, wherein the plurality of accommodating holes correspond to the electrode connecting pads, each of the plurality of accommodating holes comprises a first hole and a second hole, wherein the first hole extends through the planarization layer in the thickness direction so that each of the electrode connecting pads is at least partially exposed relative to the planarization layer, the second hole extends through at least a side face of the planarization layer away from the display backplane, a bonding material is filled in the first hole and in contact with the electrode connecting pad, and an adhesive is filled in the second hole; wherein the bonding material is used to electrically connect an electrode of a light-emitting diode (LED) chip with the electrode connecting pad, and the adhesive is used to adhere the LED chip on the planarization layer; and
the LED chip is disposed on a side face of the planarization layer away from the display backplane, and the LED chip has the electrode, wherein the electrode corresponds to at least part of the first hole and at least part of the second hole, the electrode is electrically connected with the electrode connecting pad through the bonding material, and the electrode is connected with the planarization layer through the adhesive.

13. A method for manufacturing a display backplane assembly, comprising:
preparing a planarization layer on a first surface of a display backplane, wherein electrode connecting pads are disposed on the first surface;
defining a plurality of accommodating holes on the planarization layer in a thickness direction of the planarization layer, wherein the plurality of accommodating holes correspond to the electrode connecting pads, each of the electrode connecting pads is at least partially exposed relative to the planarization layer, each of the plurality of accommodating holes comprises a first hole and a second hole, wherein the first hole extends through the planarization layer in the thickness direction so that the electrode connecting pad is at least partially exposed relative to the planarization layer, and the second hole extends through at least a side face of the planarization layer away from the display backplane;
filling a bonding material in the first hole, wherein the bonding material contacts the electrode connecting pad; and
filling an adhesive in the second hole.

14. The method of claim 13, further comprising:
transferring an LED chip to a side face of the planarization layer away from the display backplane, wherein the LED chip has an electrode, the electrode corresponds to at least part of the first hole and at least part of the second hole, the electrode is electrically connected with the electrode connecting pad through the bonding material, and the electrode is connected with the planarization layer through the adhesive.

15. A method for trimming the LED display module of claim 12, comprising:
testing an electrical connection stability of the LED chip;
removing the LED chip from the display backplane assembly on a determination that the electrical connection stability of the LED chip is abnormal; and
adding another LED chip to the display backplane assembly, wherein the another LED chip has an electrode, the electrode of the another LED chip corresponds to the at least part of the first hole and the at least part of the second hole, the electrode is electrically connected with the electrode connecting pad through the bonding material, and the electrode is connected with the planarization layer through the adhesive.

16. The method of claim 15, further comprising: heating and pressing the another LED chip to fix the another LED chip with the bonding material.
